(19) United States
(12) Patent Application Publication
(10) Pub. No.: US 2024/0191629 A1
(43) Pub. Date: Jun. 13, 2024

(54) NICKEL-BASED SUPERALLOY, SINGLE-CRYSTAL BLADE AND TURBOMACHINE

(71) Applicant: SAFRAN, Paris (FR)

(72) Inventors: Jérémy RAME, Moissy-Cramayel (FR); Edern MENOU, Moissy-Cramayel (FR)

(73) Assignee: SAFRAN, Paris (FR)

(21) Appl. No.: 18/553,416

(22) PCT Filed: Mar. 25, 2022
(86) PCT No.: PCT/FR2022/050558

§ 371 Date: Sep. 29, 2023

(30) Foreign Application Priority Data
Apr. 2, 2021 (FR) 2103436

(51) Int. Cl. F01D 5/28; C22C 19/05; C30B 29/52

(52) U.S. Cl. CPC F01D 5/288; C22C 19/056; C30B 29/52; F05D 2300/175; F05D 2300/611

(57) ABSTRACT

A nickel-based superalloy including, in weight percentages, 5.5 to 7.5% of aluminum, 1.0 to 4.0% of tantalum, 0.50 to 3.0% of titanium, 3.0 to 7.0% of cobalt, 8.0 to 12.0% of chromium, 0 to 2.5% of molybdenum, 0 to 3.0% of tungsten, 0.50 to 2.8% of rhenium, 0.05 to 0.25% of hafnium, 0 to 0.15% of silicon, the remainder consisting of nickel and unavoidable impurities.

### TECHNICAL FIELD

This disclosure relates to nickel-based superalloys for gas turbines, in particular for the fixed blades, also called distributors or rectifiers, or moving blades of a gas turbine, for example in the field of aeronautics.

### PRIOR ART

It is known to use nickel-based superalloys for the manufacture of fixed or moving single-crystal blades of gas turbines for aircraft or helicopter engines.

The main advantages of these materials are that they combine both high creep resistance at high temperatures as well as resistance to oxidation and corrosion.

Over time, nickel-based superalloys for single-crystal blades have undergone significant changes in chemical composition, with the particular purpose of improving their creep properties at high temperatures while maintaining resistance to the very aggressive environment in which these superalloys are used.

Moreover, metallic coatings adapted for these alloys have been developed in order to increase their resistance to the aggressive environment in which these alloys are used, in particular resistance to oxidation and resistance to corrosion. Additionally, a ceramic coating of low thermal conductivity, performing a thermal barrier function, can be added to reduce the temperature on the metal surface.

Typically, a complete protection system includes at least two layers.

The first layer, also called sub-layer or bonding layer, is deposited directly on the nickel-based superalloy part to be protected, also called substrate, for example a blade. The deposition step is followed by a step of diffusing the sub-layer in the superalloy. The deposition and the diffusion can also be carried out during a single step.

The materials generally used to produce this sub-layer comprise aluminum-forming metal alloys of the MCrAlY type (M=Ni (nickel) or Co (cobalt)) or a mixture of Ni and Co, Cr=chromium, Al=aluminum and Y=yttrium, or nickel aluminide type alloys (NixAly), some also containing platinum (NixAlyPtz).

The second layer, generally called thermal barrier or “TBC” in accordance with the acronym for «Thermal Barrier Coating», is a ceramic coating comprising for example yttria zirconia, also called «YSZ» in accordance with the acronym for «Yttria Stabilized Zirconia» or «YPSZ» in accordance with the acronym for «Yttria Partially Stabilized Zirconia» and having a porous structure. This layer can be deposited by various methods, such as evaporation under electron beam («EB-PVD» in accordance with the acronym for «Electron Beam Physical Vapor Deposition»), thermal spraying («APS» in accordance with the acronym for «Atmospheric Plasma Spraying» or «SPS» in accordance with the acronym for «Suspension Plasma Spraying»), or any other method allowing to obtain a porous ceramic coating with low thermal conductivity.

Due to the use of these materials at high temperatures, for example from 650° C. to 1100° C., inter-diffusion phenomena occur on a microscopic scale between the nickel-based superalloy of the substrate and the metal alloy of the sub-layer. These inter-diffusion phenomena, associated with the oxidation of the sub-layer, modify in particular the chemical composition, the microstructure and therefore the mechanical properties of the sub-layer from the manufacture of the coating, then during the use of the blade in the turbine. These inter-diffusion phenomena also modify the chemical composition, the microstructure and consequently the mechanical properties of the superalloy of the substrate under the coating. In superalloys heavily loaded with refractory elements, particularly rhenium, a secondary reaction zone (ZRS) can thus form in the superalloy under the sub-layer to a depth of several tens, or even hundreds, of micrometers. The mechanical features of this ZRS are significantly lower than those of the substrate superalloy. The formation of ZRS is undesirable because it leads to a significant reduction in the mechanical strength of the superalloy.

These evolutions of the bonding layer, associated with the stress fields related to the growth of the alumina layer which forms in service on the surface of this bonding layer, also called «TGO» in accordance with the acronym for «Thermally Grown Oxide», and the differences in thermal expansion coefficients between the different layers, generate decohesions in the interfacial zone between the sub-layer and the ceramic coating, which can lead to partial or total chipping of the ceramic coating. The metal portion (superalloy substrate and metal sub-layer) is then bared and exposed directly to the combustion gases, which increases the risk of damage to the blade and therefore to the gas turbine.

In addition, the complexity of the chemistry of these alloys can lead to a destabilization of their optimal microstructure with the appearance of particles of undesirable phases when parts formed from these alloys are maintained at high temperature. This destabilization has negative consequences on the mechanical properties of these alloys. These undesirable phases of complex crystalline structure and of fragile nature are called Topologically Close-Packed («TCP») phases.

Furthermore, foundry defects are liable to form in the parts, such as blades, during their manufacture by directional solidification. These defects are generally parasitic grains of the «Freckle» type, the presence of which can cause premature failure of the part in service. The presence of these defects, related to the chemical composition of the superalloy, generally leads to the rejection of the part, which results in an increase in production costs.

### DISCLOSURE OF THE INVENTION

This disclosure aims at proposing nickel-based superalloy compositions for the manufacture of single-crystal components, having increased performance in terms of lifespan and mechanical resistance and allowing to reduce the production costs of the part (reduction in the scrap rate) compared to existing alloys. These superalloys have higher temperature creep resistance than existing alloys while demonstrating good microstructural stability in the volume of the superalloy (low sensitivity to PTC formation), good microstructural stability under the sub-layer of coating of the thermal barrier (low sensitivity to the formation of ZRS), good resistance to oxidation and corrosion while avoiding the formation of parasitic grains of the «Freckle» type.

To this end, the present disclosure relates to a nickel-based superalloy comprising, in weight percentages, 5.5 to 7.5% of aluminum, 1.0 to 4.0% of tantalum, 0.50 to 3.0% of titanium, 3.0 to 7.0% of cobalt, 8.0 to 12.0% of chromium, 0 to 2.5% of molybdenum, 0 to 3.0% of tungsten, 0.50 to 2.8% of rhenium, 0.05 to 0.25% of hafnium, 0 to 0.15% of silicon, the remainder consisting of nickel and unavoidable impurities.

This superalloy is intended for the manufacture of single-crystal gas turbine components, such as fixed or moving blades.

Thanks to this composition of the nickel-based superalloy (Ni), the creep resistance is improved compared to existing superalloys, in particular at temperatures which can go up to 1100° C. and the adhesion of the thermal barrier is reinforced compared to that observed on existing superalloys.

This alloy therefore has improved creep resistance at high temperature. As the service life of this alloy is thus long, this alloy also has improved resistance to corrosion and oxidation. This alloy may also have improved thermal fatigue resistance.

These superalloys have a volumetric mass less than or equal to 8.50 g/cm3 (gram per cubic centimeter), preferably less than or equal to 8.20 g/cm³.

A single-crystal nickel-based superalloy part is obtained by a method of directional solidification under a thermal gradient in the lost-wax foundry. The single-crystal nickel-based superalloy comprises an austenitic matrix of face-centered cubic structure, nickel-based solid solution, known as the gamma («γ») phase. This matrix contains gamma prime («γ′») hardening phase precipitates of ordered cubic structure L1₂ of the NisAl type. The assembly (matrix and precipitates) is therefore described as a γ/γ′ superalloy.

Moreover, this composition of the nickel-based superalloy allows the implementation of a heat treatment which redissolves the γ′ phase precipitates and the γ/γ′ eutectic phases which are formed during the solidification of the superalloy. It is thus possible to obtain a single-crystal nickel-based superalloy containing γ′ precipitates of controlled size, preferably comprised between 300 and 500 nanometers (nm), and containing a small proportion of γ/γ′ eutectic phases.

The heat treatment also allows to control the volume fraction of the γ′ phase precipitates present in the single-crystal nickel-based superalloy. The percentage by volume of the γ′ phase precipitates can be greater than or equal to 50%, preferably greater than or equal to 60%, even more preferably equal to 70%.

Furthermore, a high fraction of γ′ phase precipitates hinders the movement of dislocations and promotes the hot creep resistance of the alloy. On the other hand, at lower temperature (<950° C.), the diffusion phenomena are less and the majority damage is done by shearing of the γ′ phase precipitates. Thus, at lower temperature, the intrinsic resistance of the γ′ phase precipitates is a determining factor for the static or creep mechanical strength of the alloys. The chemistry of the alloys of the invention has therefore been adjusted so as to ensure high mechanical creep resistance from 650° to 1100° C.

The major addition elements are cobalt (Co), chromium (Cr), molybdenum (Mo), rhenium (Re), tungsten (W), aluminum (Al), titanium (Ti) and tantalum (Ta).

The minor addition elements are hafnium (Hf) and silicon (Si), for which the maximum weight content is less than 1% by weight.

Among unavoidable impurities mention can for example be made of sulfur (S), carbon (C), boron (B), yttrium (Y), lanthanum (La) and cerium (Ce). Unavoidable impurities are defined as those elements which are not intentionally added to the composition and which are added with other elements. For example, the superalloy may comprise 0.005% by weight of carbon.

The addition of tungsten, chromium, cobalt, rhenium or molybdenum mainly allows to strengthen the γ austenitic matrix of face-centered cubic crystal (fcc) structure by hardening in solid solution.

The addition of aluminum (Al), titanium (Ti) or tantalum (Ta) promotes the precipitation of the hardening phase γ′-Ni₃(Al, Ti, Ta).

Rhenium (Re) allows to slow down the diffusion of chemical species within the superalloy and to limit the coalescence of γ′ phase precipitates during service at high temperature, a phenomenon which leads to a reduction in mechanical strength. Rhenium thus allows to improve the creep resistance at high temperature of the nickel-based superalloy. However, too high a concentration of rhenium can lead to the precipitation of PTC intermetallic phases, for example σ phase, P phase or μ phase, which have a negative effect on the mechanical properties of the superalloy. Too high a rhenium concentration can also cause the formation of a secondary reaction zone in the superalloy under the sub-layer, which has a negative effect on the mechanical properties of the superalloy.

The simultaneous addition of silicon and hafnium allows to improve the resistance to hot oxidation of nickel-based superalloys by increasing the adhesion of the layer of alumina (Al₂O₃) which forms on the surface of the superalloy at high temperature. This layer of alumina forms a passivation layer on the surface of the nickel-based superalloy and a barrier to the diffusion of oxygen coming from the outside towards the inside of the nickel-based superalloy. However, it is possible to add hafnium without also adding silicon or conversely add silicon without also adding hafnium and still improve the resistance to hot oxidation of the superalloy.

Furthermore, the addition of chromium or aluminum allows to improve the resistance to oxidation and to corrosion at high temperature of the superalloy. In particular, chromium is essential for increasing the hot corrosion resistance of nickel-based superalloys. However, too high a chromium content tends to reduce the solvus temperature of the γ′ phase of the nickel-based superalloy, that is to say the temperature above which the γ′ phase is completely dissolved in the γ matrix, which is undesirable. Also, the chromium concentration is comprised between 8.0 to 12.0% by weight in order to maintain a high solvus temperature of the γ′ phase of the nickel-based superalloy, for example greater than or equal to 1200° C. but also to avoid the formation of topologically close-packed phases in the γ matrix highly saturated with alloy elements such as rhenium, molybdenum or tungsten.

The addition of cobalt, which is an element close to nickel and which partially substitutes for nickel, forms a solid solution with the nickel in the γ matrix. The cobalt allows to reinforce the γ matrix, to reduce the sensitivity to the precipitation of PTC and to the formation of ZRS in the superalloy under the protective coating. However, too high a cobalt content tends to reduce the solvus temperature of the γ′ phase of the nickel-based superalloy, which is undesirable.

The addition of refractory elements, such as molybdenum, tungsten, rhenium or tantalum allows to slow down the mechanisms controlling the creep of nickel-based superalloys and which depend on the diffusion of chemical elements in the superalloy.

A very low sulfur content in a nickel-based superalloy allows to increase the resistance to oxidation and hot corrosion as well as the resistance to chipping of the thermal barrier. Thus, a low sulfur content, less than 2 ppm by weight (part per million by weight), or even ideally less than 0.5 ppm by weight, allows to optimize these properties. Such a weight content of sulfur can be obtained by producing a low-sulfur master cast or by a desulfurization method carried out after the casting. It is in particular possible to maintain a low sulfur content by adapting the superalloy production method.

Nickel-based superalloys mean superalloys whose nickel weight percentage is the majority. It is understood that nickel is therefore the element with the highest weight percentage in the alloy.

The superalloy may comprise, in weight percentages, 5.5 to 6.5% of aluminum, 1.0 to 3.0% of tantalum, 0.50 to 1.5% of titanium, 3.0 to 7.0% of cobalt, 10.0 to 12.0% of chromium, 0.5 to 1.5% of tungsten, 0.50 to 1.5% of rhenium, 0.05 to 0.25% of hafnium, 0 to 0.15% of silicon, the remainder consisting of nickel and unavoidable impurities.

The superalloy may comprise, in weight percentages, 6.5 to 7.5% of aluminum, 1.0 to 3.0% of tantalum, 0.50 to 1.5% of titanium, 3.0 to 7.0% of cobalt, 10.0 to 12.0% of chromium, 0.5 to 1.5% of tungsten, 0.50 to 1.5% of rhenium, 0.05 to 0.25% of hafnium, 0 to 0.15% of silicon, the remainder consisting of nickel and unavoidable impurities.

The superalloy may comprise, in weight percentages, 6.0 to 7.0% of aluminum, 1.0 to 4.0% of tantalum, 0.50 to 2.5% of titanium, 3.0 to 7.0% of cobalt, 8.0 to 10.0% of chromium, 1.5 to 2.5 of molybdenum, 0 to 2.5% of tungsten, 1.5 to 2.5% of rhenium, 0.05 to 0.25% of hafnium, 0 to 0.15% of silicon, the remainder consisting of nickel and unavoidable impurities.

The superalloy may comprise, in weight percentages, 6.0% of aluminum, 2.0% of tantalum, 1.0% of titanium, 5.0% of cobalt, 11.0% of chromium, 1.0% of tungsten, 1.0% of rhenium, 0.10% of hafnium, 0.10% of silicon, the remainder consisting of nickel and unavoidable impurities.

The superalloy may comprise, in weight percentages, 7.0% of aluminum, 2.0% of tantalum, 1.0% of titanium, 5.0% of cobalt, 11.0% of chromium, 1.0% of tungsten, 1.0% of rhenium, 0.10% of hafnium, 0.10% of silicon, the remainder consisting of nickel and unavoidable impurities.

The superalloy may comprise, in weight percentages, 6.5% of aluminum, 3.0% of tantalum, 1.0% of titanium, 5.0% of cobalt, 9.0% of chromium, 1.5% of molybdenum, 2.0% of tungsten, 2.0% of rhenium, 0.10% of hafnium, 0.10% of silicon, the remainder consisting of nickel and unavoidable impurities.

The superalloy may comprise, in weight percentages, 6.5% of aluminum, 2.0% of tantalum, 2.0% of titanium, 5.0% of cobalt, 9.0% of chromium, 2.0% of molybdenum, 2.0% of rhenium, 0.10% of hafnium, 0.10% of silicon, the remainder consisting of nickel and unavoidable impurities.

The present disclosure also relates to a single-crystal blade for a turbomachine comprising a superalloy as defined above.

This blade therefore has improved resistance to creep at high temperatures. This blade therefore has improved resistance to oxidation and corrosion.

In some embodiments, the blade may comprise a protective coating including a metal sub-layer deposited on the superalloy and a ceramic thermal barrier deposited on the metal sub-layer.

Thanks to the composition of the nickel-based superalloy, the formation of a secondary reaction zone in the superalloy resulting from interdiffusion phenomena between the superalloy and the sub-layer is avoided, or limited.

In some embodiments, the metal sub-layer can be an alloy of the MCrAlY type or an alloy of the nickel aluminide type.

In some embodiments, the ceramic thermal barrier may be a yttria-zirconia-based material or any other ceramic (zirconia-based) coating with low thermal conductivity.

In some embodiments, the blade may have a structure oriented in a <001> crystallographic direction.

This orientation generally gives the blade the optimum mechanical properties.

This disclosure also relates to a turbomachine comprising a blade as defined above.

### BRIEF DESCRIPTION OF THE DRAWINGS

Other features and advantages of the object of this presentation will emerge from the following description of embodiments, given by way of non-limiting examples, with reference to the appended FIGURES.

FIG. 1 is a schematic view in longitudinal section of a turbomachine.

### DETAILED DESCRIPTION

Nickel-based superalloys are intended for the manufacture of single-crystal blades by a directional solidification method in a thermal gradient. The use of a single-crystal seed or of a grain selector at the start of solidification allows to obtain this single-crystal structure. The structure is oriented for example in a <001> crystallographic direction which is the orientation which generally confers the optimum mechanical properties on the superalloys.

Solidified raw nickel-based single-crystal superalloys have a dendritic structure and consist of γ′ Ni₃(Al, Ti, Ta) precipitates dispersed in a γ matrix of face-centered cubic structure, nickel-based solid solution. These γ′ phase precipitates are distributed heterogeneously in the volume of the single crystal due to chemical segregations resulting from the solidification method. Moreover, γ/γ′ eutectic phases are present in the inter-dendritic regions and constitute preferential crack initiation sites. These γ/γ′ eutectic phases are formed at the end of solidification. In addition, the γ/γ′ eutectic phases are formed to the detriment of the fine precipitates (size less than a micrometer) of the γ′ hardening phase. These γ′ phase precipitates constitute the main source of hardening of nickel-based superalloys. Also, the presence of residual γ/γ′ eutectic phases does not allow to optimize the hot creep resistance of the nickel-based superalloy.

It has in fact been shown that the mechanical properties of superalloys, in particular creep resistance, were optimal when the precipitation of the γ′ precipitates was ordered, that is to say that the γ′ phase precipitates are aligned regularly, with a size ranging from 300 to 500 nm, and when all the γ/γ′ eutectic phases were redissolved.

Solidified raw nickel-based superalloys are therefore heat-treated to obtain the desired distribution of the different phases. The first heat treatment is a microstructure homogenization treatment which has the purpose of dissolving the γ′ phase precipitates and to eliminate the γ/γ′ eutectic phases or to significantly reduce their volume fraction. This treatment is carried out at a temperature above the solvus temperature of the γ′ phase and below the starting melting temperature of the superalloy (T_{solidus}). Quenching is then carried out at the end of this first heat treatment to obtain a fine and homogeneous dispersion of the γ′ precipitates. Tempering heat treatments are then carried out in two steps, at temperatures below the solvus temperature of the γ′ phase. During a first step, to make the γ′ precipitates grow and obtain the desired size, then during a second step, to increase the volume fraction of this phase to about 70% at room temperature.

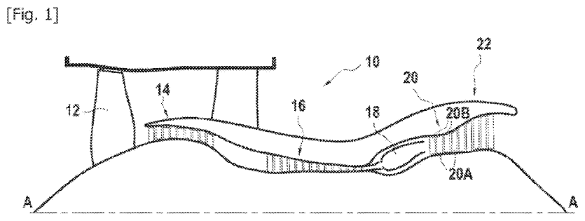

FIG. 1 shows, in section along a vertical plane passing through its main axis A, a bypass turbojet engine 10. The bypass turbojet engine 10 includes, from upstream to downstream depending on the circulation of the air flow, a fan 12, a low pressure compressor 14, a high pressure compressor 16, a combustion chamber 18, a high pressure turbine 20, and a low pressure turbine 22.

The high pressure turbine 20 comprises a plurality of moving blades 20A rotating with the rotor and rectifiers 20B (fixed blades) mounted on the stator. The stator of the turbine 20 comprises a plurality of stator rings 24 disposed opposite the moving blades 20A of the turbine 20.

These properties make these superalloys interesting candidates for the manufacture of single-crystal parts intended for the hot portions of turbojet engines.

It is therefore possible to manufacture a moving blade 20A or a rectifier 20B for a turbomachine comprising a superalloy as defined above.

It is also possible to manufacture a moving blade 20A or a stator 20B for a turbomachine comprising a superalloy as defined previously coated with a protective coating comprising a metal sub-layer.

A turbomachine can in particular be a turbojet engine such as a bypass turbojet engine 10. The turbomachine can also be a straight turbojet engine, a turboprop engine or a turboshaft engine.

### EXAMPLES

Four single-crystal nickel-based superalloys in this presentation (Ex 1 to Ex 4) were studied and compared to seven commercial single-crystal superalloys (reference alloys): MC2® (CEx 1), AM3® (CEx 2), RR2000® (CEx 3), CMSX-6® (CEx 4), AM1® (CEx 5), CMSX-4 Plus Mod C® (CEx 6) and CMSX-4® (CEx 7). The chemical composition of each of the single-crystal superalloys is given in Table 1, the CEx 3 composition further including 1.0% by weight of vanadium (V). All these superalloys are nickel-based superalloys, that is to say that 100% of the presented compositions consist of nickel and unavoidable impurities.

TABLE 1

| | Al | Ta | Ti | Co | Cr | Mo | W | Re | Hf | Si |
|---|---|---|---|---|---|---|---|---|---|---|
| Ex 1 | 6.0 | 2.0 | 1.0 | 5.0 | 11.0 | 0 | 10. | 1.0 | 0.10 | 0.10 |
| Ex 2 | 7.0 | 2.0 | 1.0 | 5.0 | 11.0 | 0 | 1.0 | 1.0 | 0.10 | 0.10 |
| Ex 3 | 6.5 | 3.0 | 1.0 | 5.0 | 9.0 | 1.5 | 2.0 | 2.0 | 0.10 | 0.10 |
| Ex 4 | 6.5 | 2.0 | 2.0 | 5.0 | 9.0 | 2.0 | 0 | 2.0 | 0.10 | 0.10 |
| CEx 1 | 5.0 | 6.0 | 1.5 | 5.0 | 8.0 | 2.0 | 0 | 8.0 | 0 | 0 |
| CEx 2 | 6.0 | 3.5 | 2.0 | 5.5 | 8.0 | 2.2 | 0 | 5.0 | 0 | 0 |
| CEx 3 | 5.5 | 0 | 4.0 | 15.0 | 10.0 | 3.0 | 0 | 0 | 0 | 0 |
| CEx 4 | 4.85 | 2.0 | 4.75 | 5.0 | 9.8 | 3.0 | 0 | 0 | 0.11 | 0 |
| CEx 5 | 5.3 | 8.0 | 1.2 | 6.5 | 7.5 | 2.0 | 0 | 5.5 | 0.05 | 0 |
| CEx 6 | 5.7 | 8.0 | 0.85 | 10.0 | 3.5 | 0.60 | 4.8 | 6.0 | 0.10 | 0 |
| CEx 7 | 5.6 | 6.5 | 1.0 | 9.0 | 6.5 | 0.60 | 3.0 | 6.0 | 0.10 | 0 |

### Volumetric Mass

The volumetric mass at room temperature of each superalloy was estimated using a modified version of Hull's formula (F.C. Hull, Metal Progress, November 1969, pp 139-140). This empirical equation was proposed by Hull. The empirical equation is based on a law of mixtures and comprises corrective terms deduced from an analysis by linear regression of experimental data (chemical compositions and measured volumetric masses) concerning 235 nickel-based, cobalt-based and iron-based superalloys. This Hull formula was modified, in particular to take into account elements such as rhenium, from 272 nickel-based, cobalt-based and iron-based superalloys. The modified Hull formula is:

D=100/[Σ(% X/Dx)]+ΣAₓ×% X (1)

where Dx are the volumetric masses of the elements Cr, Ni, . . . , X and D is the volumetric mass of the superalloy, the volumetric masses being expressed in g/cm³, where Aₓ is a coefficient expressed in g/cm³ of the elements Cr, Ni, . . . , X and are the following: A_{Ni}=−0.0011; A_{Al}=0.0622; A_{Ta}=0.0121; A_{Ti}=0.0317; A_{Co}=−0.0001; A_{Cr}=−0.0034; A_{Mo}=0.0033; A_{W}=0.0033; A_{Re}=0.0036; A_{Hf}=0.0156. where % X are the contents, expressed in weight percentages, of the superalloy elements Cr, Ni, . . . , X.

The volumetric masses calculated for the alloys of the invention are less than 8.20 g/cm³ (see Table 2).

The volumetric mass is of prime importance for applications of rotating components such as turbine blades. Indeed, an increase in the density of the alloy of the blades imposes a reinforcement of the disc carrying them, and therefore another additional cost in weight. Alloys of similar density that can compete with Ex 1 to Ex 4 alloys, from a density point of view, are CEx 3 and CEx 4 alloys. CEx 3 and CEx 4 alloys do not meet current superalloy development standards for blades. In particular, the composition of the CEx 3 and CEx 4 alloys comes from developments for conventional foundry and not for foundry by directional solidification.

### Susceptibility to ZRS Formation

To estimate the sensitivity of nickel-based superalloys containing rhenium to the formation of ZRS, Walston (document U.S. Pat. No. 5,270,123) established the following equation:

[ZRS (%)]^{1/2}=13.88(% Re)+4.10(% W)−7.07(% Cr)−2.94(% Mo)−0.33(% Co)+12.13 (2)

where ZRS (%) is the linear percentage of ZRS in the superalloy under the coating and where the concentrations of the alloy elements are in atomic percentages.

This equation (2) was obtained by multiple linear regression analysis from observations made after aging for 400 hours at 1093° C. (degree centigrade) of various nickel-based superalloy samples, close to the René N6® composition, under a NiPtAl coating.

The higher the value of the parameter [ZRS (%)]^{1/2}, the more the superalloy is sensitive to the formation of ZRS. In particular, negative values are representative of low sensitivity with respect to this defect.

Thus, as can be seen in Table 2, for superalloys Ex 1 to Ex 4, the values of the parameter [ZRS (%)]^{1/2} are all significantly negative and these superalloys therefore have low sensitivity to the formation of ZRS under a NitPtAl coating, a coating which is often present for turbine blade applications (rotating blade and/or distributor).

### No-Freckles Parameter (NFP)

NFP=[% Ta+1.5% Hf+0.5% Mo−0.5% % Ti)]/[% W+1.2% Re)] (3)

where % Cr, % Ni, . . . % X are the contents, expressed in weight percentages, of the elements of the superalloy Cr, Ni, . . . , X.

The NFP parameter allows to quantify the sensitivity to the formation of parasitic grains of the “Freckles” type during the directional solidification of the part (document U.S. Pat. No. 5,888,451). To avoid the formation of “Freckle” type defects, the NFP parameter must be greater than or equal to 0.7. Low sensitivity to this type of defect is an important parameter because it implies a low scrap rate related to this defect during the manufacture of parts.

As can be seen in Table 2, superalloys Ex 1 to Ex 4 all have an NFP parameter greater than or equal to 0.7. Commercial alloys containing rhenium such as CEx 6 or CEx 7 have higher sensitivities to the formation of this type of defect as indicated in Table 2. A low sensitivity to this type of defect is an important parameter because it implies a low scrap rate related to this defect during the manufacture of parts.

### Cost of Super Alloys

The cost per kilogram of Ex 1 to Ex 4 superalloys is calculated based on the composition of the superalloy and the costs of each compound (updated April 2020). This cost is given as an indication.

The estimated cost of Ex 1 to Ex 4 superalloys is around 80-100$/kg. This cost is higher than alloys not containing rhenium such as CEx 5 or CEx 1 but lower than alloys containing rhenium such as CEx 6 or CEx 7. The alloys of the invention are competitive given their position compared to the reference alloys.

Table 2 shows different parameters for the superalloys Ex 1 to Ex 4 and CEx 1 to CEx 7.

TABLE 2

| | Volumetric | | | |
|---|---|---|---|---|
| | mass (1) | | | Cost |
| | (g/cm³) | [ZRS(%)]^{1/2} | NFP | ($/kg) |
| Ex 1 | 8.04 | −67.0 | 0.75 | 82 |
| Ex 2 | 7.95 | −66.0 | 0.75 | 82 |
| Ex 3 | 8.18 | −50.0 | 0.77 | 106 |
| Ex 4 | 8.03 | −53.0 | 0.90 | 104 |
| CEx 1 | 8.67 | −48.3 | 0.78 | 50 |
| CEx 2 | 8.29 | −49.8 | 0.75 | 46 |
| CEx 3 | 7.88 | −71.6 | — | 53 |
| CEx 4 | 8.01 | −68.7 | — | 50 |
| CEx 5 | 8.64 | −47.8 | 1.54 | 51 |
| CEx 6 | 8.93 | 8.5 | 0.68 | 180 |
| CEx 7 | 8.71 | −24.0 | 0.67 | 135 |

### Solvus Temperature of the γ′ Phase

The Thermo-Calc software (TCNI9.1 database, Thermo-Calc Software AB, Sweden) based on the CALPHAD method was used to calculate the solvus temperature of the γ′ phase at equilibrium.

As can be seen in Table 3, the superalloys Ex 1 to Ex 4 have a solvus temperature γ′ greater than 1200° ° C.

### Heat Treatment Interval (TTH)

The Thermo-Calc software (TCNI9.1 database) based on the CALPHAD method was used to calculate the heat treatment interval of the superalloys.

The manufacturability of the alloys of the invention was also estimated from the possibility of industrially redissolving the γ′ phase precipitates to optimize the mechanical properties of the alloys. The heat treatment interval was estimated from the calculation of the solidus temperature and solvus temperature of the γ′ phase precipitates of the alloys. Ex 1 to Ex 4 alloys all have high heat treatment windows, greater than 50° C., which is compatible with industrial furnaces. Note that the CEx 7 or CEx 5 reference alloys have much more restricted heat treatment intervals and are therefore less easily heat treatable without risk of burning the alloy.

### Phase Volume Fraction γ′

The Thermo-Calc software (TCNI9.1 database) based on the CALPHAD method was used to calculate the volume fraction (in volume percentage) of γ′ phase at equilibrium in the superalloys Ex 1 to Ex 4 and CEx 1 to CEx 7 at 750° C. and 1100° C.

As can be seen in Table 3, the superalloys Ex 1 to Ex 4 contain γ′ phase volume fractions greater than or comparable to the γ′ phase volume fractions of commercial superalloys CEx 1 to CEx 7.

Thus, the combination of a high γ′ solvus temperature and high γ′ phase volume fractions for the superalloys Ex 1 to Ex 4 is favorable to good creep resistance at high temperatures and very high temperatures, for example at 1100° C.

### Volume Fraction of σ-Type PTC

The Thermo-Calc software (TCNI9.1 database) based on the CALPHAD method was used to calculate the volume fraction (in volume percentage) of σ phase at equilibrium in the superalloys Ex 1 to Ex 4 and CEx 1 to CEx 7 at 750° C. (see table 3).

The calculated σ phase volume fractions are relatively low, reflecting a low sensitivity to PTC precipitation.

TABLE 3

| | | | Volume fraction | | Volume fraction |
|---|---|---|---|---|---|
| | Tₛₒₗᵥᵤₛ | | of γ′ phase | | of σ-type PTC |
| | γ′ | TTH | (% vol) | | (% vol) |
| | (° C.) | (° C.) | 750° C. | 1100° C. | 750° C. |
| Ex 1 | 1201 | 151 | 69.0 | 26.0 | 0 |
| Ex 2 | 1245 | 90 | 79.0 | 42.0 | 0 |
| Ex 3 | 1264 | 69 | 82.0 | 45.0 | 2.8 |
| Ex 4 | 1260 | 57 | 79.0 | 48.0 | 3.0 |
| CEx 1 | 1263 | 54 | 70.1 | 43.6 | 5.9 |
| CEx 2 | 1264 | 53 | 80.8 | 50.7 | 3.3 |
| CEx 3 | 1201 | 101 | 68.7 | 37.7 | 4.0 |
| CEx 4 | 1246 | 19 | 69.2 | 47.7 | 3.3 |
| CEx 5 | 1287 | 20 | 70.1 | 47.1 | 2.9 |
| CEx 6 | 1304 | 22 | 14.0 | 53.0 | 2.2 |
| CEx 7 | 1271 | 51 | 62.9 | 45.8 | 2.2 |

At a similar density (˜8 g/cm³), the Ex 2 and Ex 4 alloys have solvus temperatures significantly higher than the solvus temperature of CEx 3 (+44° C. and +59° C. respectively) and fractions of γ′ phase precipitates greater than this same alloy at 750° ° C. and 1100° C. (Table 2). Compared to CEx 4, Ex 2 and Ex 4 have respectively similar solvus. At 750° C., the fractions of γ′ phase precipitates of the Ex 2 and Ex 4 alloys are higher than those of CEx 4 (+10%). At 1100° C., Ex 2 has a fraction of γ′ phase precipitates slightly less than CEx 4 (−6%) while Ex 4 has a fraction of γ′ phase precipitates similar to CEx 4. In the same way, Ex 3 has a solvus temperature similar to CEx 2 with a fraction of γ′ phase precipitates at 750° C. similar and slightly less than 1100° C. Nevertheless, Ex 3 has a lower density of 0.1 g/cm³ compared to CEx 2. Since the density variation range of nickel-based superalloys is generally between 8 and 9 g/cm³, this 10% difference is significant. The Ex 2 and Ex 4 alloys have TCP volume fractions of 0 and 3% respectively at 750° C., which is similar or lower than the TCP fractions of the reference alloys CEx 1 (5.9%), CEx 3 (4%) and CEx 4 (3.3%). Ex 3 has a slightly lower TCP content at 750° ° C. than CEx 2.

According to these predictions, at equivalent density, the Ex 2 and Ex 4 alloys have a chemical composition and a microstructure which allows to consider a mechanical strength superior to that of the reference alloys CEx 3 and CEx 4. In addition, Ex 3 should have a mechanical strength similar to CEx 2 with a lower density.

The alloys of the invention have been designed so as to maintain a high resistance to corrosion (˜900° C.) and oxidation)(˜1100° ° C. at high temperature. The flow that circulates through the turbines of turbojet engines is loaded with products that are generally a result of the fuel combustion reaction, but which also include water, sands, and salts contained in the incoming air ingested by the turbomachine. The fuel also contains impurities and sulfur products (always existing regardless of the cleanliness of the fuel). Thus, on the one hand, the alloys oxidize under the operating conditions imposed by the engines (temperature, pressure) by reactions with the various gases contained (O₂ (g), COₓ, NOₓ, H₂O, etc.) in the engine environment. On the other hand, they can undergo phenomena of accelerated corrosion (known as hot corrosion) by reaction with alkaline sulfates M₂SO₄ (M=Na, K, Ca) liquid around 900° ° C. which can be present in the deposits that form on the surface of the parts. For better resistance to these two phenomena, oxidation and corrosion, attempts are made to form protective oxides of the alumina type (Al₂O₃) for oxidation and chromia (Cr₂O₃) for corrosion. Thus, the corrosion and oxidation properties of the alloys of the invention were estimated from the chromium and aluminum content of the alloys.

The alloys of the invention have chromium contents similar to those of the CEx 3 and CEx 4 alloys and higher than those of the other reference alloys. The aluminum contents of the alloys of the invention are greater than or equal to those of the reference alloys. The oxidation and corrosion resistance of these alloys is assumed to be similar or superior to that of the CEx 3 and CEx 4 reference alloys and superior to that of the other reference alloys.

According to the different criteria taken into account, the example alloys of the invention thus have a strong potential for high temperature applications, in particular for the manufacture of turbine blades, combining an adequate compromise combining low density, high mechanical strength, low sensitivity to the formation of defects (PTC, ZRS, foundry defects), while maintaining high resistance to oxidation and corrosion.

Although the present disclosure has been described with reference to a specific embodiment, it is obvious that various modifications and changes can be made to these examples without departing from the general scope of the invention as defined by the claims. Furthermore, individual features of the different embodiments discussed may be combined in additional embodiments. Therefore, the description and drawings should be considered in an illustrative rather than a restrictive sense.

1. A nickel-based superalloy comprising, in weight percentages, 5.5 to 7.5% of aluminum, 1.0 to 4.0% of tantalum, 0.50 to 3.0% of titanium, 3.0 to 7.0% of cobalt, 8.0 to 12.0% of chromium, 0 to 2.5% of molybdenum, 0 to 3.0% of tungsten, 0.50 to 2.8% of rhenium, 0.05 to 0.25% of hafnium, 0 to 0.15% of silicon, the remainder consisting of nickel and unavoidable impurities.

2. The superalloy according to claim 1, comprising, in weight percentages, 5.5 to 6.5% of aluminum, 1.0 to 3.0% of tantalum, 0.50 to 1.5% of titanium, 3.0 to 7.0% of cobalt, 10.0 to 12.0% of chromium, 0.5 to 1.5% of tungsten, 0.50 to 1.5% of rhenium, 0.05 to 0.25% of hafnium, 0 to 0.15% of silicon, the remainder consisting of nickel and unavoidable impurities.

3. The superalloy according to claim 1, comprising, in weight percentages, 6.5 to 7.5% of aluminum, 1.0 to 3.0% of tantalum, 0.50 to 1.5% of titanium, 3.0 to 7.0% of cobalt, 10.0 to 12.0% of chromium, 0.5 to 1.5% of tungsten, 0.50 to 1.5% of rhenium, 0.05 to 0.25% of hafnium, 0 to 0.15% of silicon, the remainder consisting of nickel and unavoidable impurities.

4. The superalloy according to claim 1, comprising, in weight percentages, 6.0 to 7.0% of aluminum, 1.0 to 4.0% of tantalum, 0.50 to 2.5% of titanium, 3.0 to 7.0% of cobalt, 8.0 to 10.0% of chromium, 1.5 to 2.5 of molybdenum, 0 to 2.5% of tungsten, 1.5 to 2.5% of rhenium, 0.05 to 0.25% of hafnium, 0 to 0.15% of silicon, the remainder consisting of nickel and unavoidable impurities.

5. The superalloy according to claim 1, comprising, in weight percentages, 6.0% of aluminum, 2.0% of tantalum, 1.0% of titanium, 5.0% of cobalt, 11.0% of chromium, 1.0% of tungsten, 1.0% of rhenium, 0.10% of hafnium, 0.10% of silicon, the remainder consisting of nickel and unavoidable impurities.

6. The superalloy according to claim 1, comprising, in weight percentages, 7.0% of aluminum, 2.0% of tantalum, 1.0% of titanium, 5.0% of cobalt, 11.0% of chromium, 1.0% of tungsten, 1.0% of rhenium, 0.10% of hafnium, 0.10% of silicon, the remainder consisting of nickel and unavoidable impurities.

7. The superalloy according to claim 1, comprising, in weight percentages, 6.5% of aluminum, 3.0% of tantalum, 1.0% of titanium, 5.0% of cobalt, 9.0% of chromium, 1.5% of molybdenum, 2.0% of tungsten, 2.0% of rhenium, 0.10% of hafnium, 0.10% of silicon, the remainder consisting of nickel and unavoidable impurities.

8. The superalloy according to claim 1, comprising, in weight percentages, 6.5% of aluminum, 2.0% of tantalum, 2.0% of titanium, 5.0% of cobalt, 9.0% of chromium, 2.0% of molybdenum, 2.0% of rhenium, 0.10% of hafnium, 0.10% of silicon, the remainder consisting of nickel and unavoidable impurities.

9. A single-crystal blade for a turbomachine comprising a superalloy according to claim 1.

10. The blade according to claim 9, comprising a protective coating comprising a metal sub-layer deposited on the superalloy and a ceramic thermal barrier deposited on the metal sub-layer.

11. The blade according to claim 9, having a structure oriented in a <001> crystallographic direction.

12. A turbomachine comprising a blade according to claim 9.
